(19) United States
(12) Patent Application Publication
(10) Pub. No.: US 2025/0292806 A1
(43) Pub. Date: Sep. 18, 2025

(54) SEMICONDUCTOR DEVICE AND SEMICONDUCTOR MODULE

(71) Applicant: SK hynix Inc., Gyeonggi-do (KR)

(72) Inventor: Joo Hyung KIM, Gyeonggi-do (KR)

(21) Appl. No.: 19/038,086

(22) Filed: Jan. 27, 2025

(30) Foreign Application Priority Data
Mar. 14, 2024 (KR) 10-2024-0035519

(51) Int. Cl. G11C 5/06; G06F 11/22; G06F 11/273; H01L 25/07

(52) U.S. Cl. CPC G11C 5/063; G06F 11/2215; G06F 11/2733; H01L 25/072

(57) ABSTRACT

Embodiments of the present disclosure provide shared package balls for supplying a signal to a semiconductor package including a plurality of semiconductor chips, and provide a method capable of driving the plurality of semiconductor chips using the shared package balls while reducing the number of package balls even when the number of semiconductor chips included in the semiconductor package is increased.

### CROSS-REFERENCES TO RELATED APPLICATION

The present application claims priority under 35 U.S.C. 119(a) to Korean patent application number 10-2024-0035519 filed on Mar. 14, 2024, which is incorporated herein by reference in its entirety.

### TECHNICAL FIELD

Embodiments of the present disclosure relate to a semiconductor device and a semiconductor module.

### BACKGROUND

As an example of a semiconductor device, a storage device may include memory that stores data. The storage device may include a controller that controls the operation of the memory.

In some cases, the storage device may include a plurality of memories or a plurality of controllers.

As the number of semiconductor chips, such as memories and controllers, included in storage devices increases, it may not be easy to implement a line structure for supplying signals to a plurality of semiconductor chips or to implement a method for operating a plurality of semiconductor chips.

### SUMMARY

Embodiments of the present disclosure may provide a method for easily implementing a structure for supplying signals to a semiconductor device including a plurality of semiconductor chips, and for simply implementing a method for operating a plurality of semiconductor chips included in a semiconductor device.

Embodiments of the present disclosure may provide a semiconductor device, comprising a first semiconductor chip including a first power signal bump and a plurality of first input and output (input/output) bumps, which includes a first power control input/output bump, a second semiconductor chip including a second power signal bump and a plurality of second input/output bumps, a first power signal package ball electrically connected to the first power signal bump through a first power signal line, a second power signal package ball electrically connected to the second power signal bump through a second power signal line, and a power control package ball electrically connected to the first power control input/output bump through a power control line and electrically connected to the second power signal package ball through a connection line.

Embodiments of the present disclosure may provide a semiconductor device, comprising a first controller including a first power signal bump and a plurality of first input and output (input/output) bumps, the first power signal bump electrically connected to a first power signal package ball, a second controller including a second power signal bump and a plurality of second input/output bumps, the second power signal bump electrically separated from the first power signal bump and electrically connected to at least one of the plurality of first input/output bumps, and at least one memory receiving a signal from at least one of the first controller or the second controller.

Embodiments of the present disclosure may provide a semiconductor module, comprising a base substrate, a package substrate disposed on the base substrate and including a first power signal package ball, a second power signal package ball, and a power control package ball, a first semiconductor chip disposed on the package substrate and including a first power signal bump and a first power control input/output bump, the first power signal bump electrically connected to the first power signal package ball through a first power signal line, the first power control input and output (input/output) bump electrically connected to the power control package ball through a power control line, and a second semiconductor chip disposed on the package substrate and including a second power signal bump electrically connected to the second power signal package ball through a second power signal line, and electrically connected to the first power control input/output bump.

According to embodiments of the present disclosure, it is possible to simply implement a structure for supplying signals to a plurality of semiconductor chips included in a semiconductor device and an operation method according to the signal supply.

### BRIEF DESCRIPTION OF THE DRAWINGS

FIG. 1 is a view illustrating a schematic configuration of a storage device according to embodiments of the present disclosure;

FIG. 2A and FIG. 2B is a view illustrating a structure of a semiconductor module in which a storage device is disposed according to embodiments of the present disclosure;

FIG. 3 is a view illustrating a schematic configuration of a plurality of controllers included in a storage device according to embodiments of the present disclosure;

FIG. 4 is a view illustrating a structure of supplying signals to a plurality of controllers included in a storage device according to embodiments of the present disclosure;

FIG. 5 is a view illustrating another structure of supplying signals to a plurality of controllers included in a storage device according to embodiments of the present disclosure;

FIGS. 6 and 7 are views illustrating a booting method of a plurality of controllers included in the storage device illustrated in FIG. 5;

FIG. 8 is a view illustrating a connection structure between a plurality of controllers included in a storage device according to embodiments of the present disclosure; and

FIGS. 9 and 10 are views illustrating another structure of supplying signals to a plurality of controllers included in a storage device according to embodiments of the present disclosure.

### DETAIL DESCRIPTION

In the following description of embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of this disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all meanings of the term “can”.

Hereinafter, various embodiments of the present disclosure will be described in detail with reference to accompanying drawings.

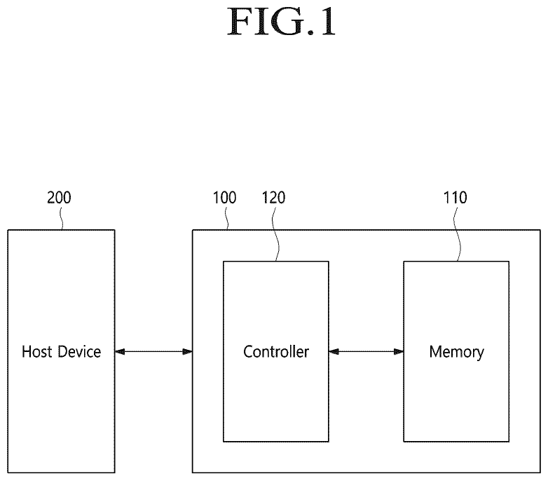

FIG. 1 is a view illustrating a schematic configuration of a storage device 100 according to embodiments of the present disclosure.

Referring to FIG. 1, the storage device 100 may include at least one memory 110. The storage device 100 may include a controller 120 that controls the operation of the memory 110. In this disclosure, the storage device 100 may be referred to as a semiconductor device or a semiconductor package. In this disclosure, the memory 110 and controller 120 included in the storage device 100 may be referred to as a semiconductor chip or chiplet.

The memory 110 may be, e.g., a volatile memory such as DRAM, SDRAM, DDR SDRAM, and LPDDR SDRAM, but embodiments of the present disclosure are not limited thereto. In some embodiments, the memory 110 may be a nonvolatile memory such as a NAND flash memory, a three-dimensional (3D) NAND flash memory, or a NOR flash memory. In other embodiments, a portion of the memory 110 included in the storage device 100 may be volatile memory, and another portion thereof may be non-volatile memory.

In some embodiments, the memory 110 may be one of various types of memories such as resistive RAM, phase change memory, magnetoresistive memory, ferroelectric memory, or spin injection magnetization inversion memory. In other embodiments, the memory 110 may be a processing-in-memory including an arithmetic function or a data processing function. In this disclosure, the memory 110 may be referred to as a memory device.

The memory 110 may include a plurality of storage blocks. Each of the plurality of storage blocks may include a plurality of memory cells. The plurality of storage blocks may be divided into a plurality of banks, which are units controlled by the controller 120.

The controller 120 may receive a command from the outside (e.g., a host device 200) and control the operation of the memory 110 based on the received command. Further, the controller 120 may control the operation of the memory 110 based on a command generated therein.

The controller 120 may transmit, to the memory 110, a command or address for controlling the operation of the memory 110. The controller 120 may control, e.g., an operation of writing data to the memory 110. The controller 120 may control an operation of reading data written to the memory 110. Data may be transmitted and received between the controller 120 and the memory 110.

The controller 120 may control a data preserve operation (e.g., a refresh operation or a patrol scrub operation) or an erase operation on data written to the memory 110 according to the type of the memory 110.

The controller 120 may control the operation of the memory 110 based on a command received from the host device 200.

The host device 200 may be, e.g., a computer, an ultra-mobile PC (UMPC), a workstation, a personal digital assistant (PDA), a tablet, a mobile phone, a smartphone, an e-book, a portable multimedia player (PMP), a portable game console, a navigation device, a black box, a digital camera, a digital camera, a digital multimedia broadcasting (DMB) player, a smart television, a digital voice recorder, a digital voice player, a digital video recorder, a digital video player, storage constituting a data center, one of various electronic devices constituting a telematics network, a radio frequency identification (RFID) device, and a moving device (e.g., a vehicle, robot, or drone) capable of driving under human control or autonomous driving. Alternatively, the host device 200 may be a virtual/augmented reality (VR/AR) device that provides two-dimensional (2D) or three-dimensional (3D) virtual reality images or augmented reality images. The host device 200 may be any of various electronic devices that require the storage device 100 capable of storing data.

The host device 200 may include at least one operating system. The operating system may generally manage and control the functions and operations of the host device 200, and may control mutual operations between the host device 200 and the storage device 100. The operating system may be divided into a general operating system and a mobile operating system according to the mobility of the host device 200.

The controller 120 and the host device 200 may be devices separated from each other. In some embodiments, the controller 120 and the host device 200 may be integrated and implemented as one device, or some components or functions of the controller 120 may be implemented to be included in the host device 200. Hereinafter, for convenience, an example is described in which the controller 120 and the host device 200 are separated from each other.

Each of the controller 120 and the memory 110 included in the storage device 100 may be provided as a semiconductor chip. The controller 120 and the memory 110 may be provided in separate semiconductor package forms. Alternatively, the controller 120 and the memory 110 may be provided in the form of a single semiconductor package. In some embodiments, a semiconductor package including semiconductor chips other than the controller 120 and the memory 110 may be included in the storage device 100.

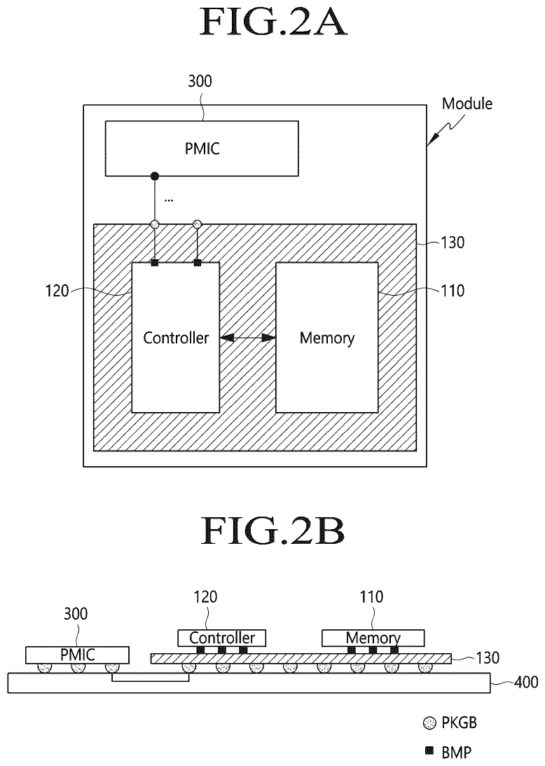

FIG. 2A and FIG. 2B is a view illustrating a structure of a semiconductor module in which a storage device 100 is disposed according to embodiments of the present disclosure.

Referring to FIG. 2A and FIG. 2B, a structure in which a controller 120 and a memory 110 included in the storage device 100 are implemented in the form of a single package is shown. The controller 120 and the memory 110 may be disposed on the package substrate 130, for example. The package substrate 130 may be, e.g., a substrate formed of silicon, but embodiments of the present disclosure are not limited thereto.

Each of the controller 120 and the memory 110 may be coupled to a plurality of bumps BMP. In some cases, the plurality of bumps BMP may be part of the controller 120 or the memory 110. Each of the plurality of bumps BMP may be electrically connected to the package substrate 130. The package substrate 130 may include a plurality of package balls PKGB. Each of the plurality of package balls PKGB may be electrically connected to the bump BMP.

The semiconductor package including the controller 120 and the memory 110 may be disposed on the base substrate 400.

The base substrate 400 and the semiconductor package disposed on the base substrate 400 together may be referred to as a semiconductor module. The semiconductor module may include at least one semiconductor chip or circuit other than the semiconductor package such as the storage device 100.

For example, the power management circuit or power management integrated circuit (PMIC) 300 may be disposed on the base substrate 400. The power management circuit 300 may be positioned outside the storage device 100. In some embodiments, the power management circuit 300 may be included in the storage device 100. In this case, the controller 120, the memory 110, and the power management circuit 130 are provided in the form of a single semiconductor package and may constitute the storage device 100.

The power management circuit 300 is positioned outside the storage device 100 and may supply power to the storage device 100. The power management circuit 300 may be electrically connected to the package ball PKGB included in the package substrate 130 of the storage device 100. Power supplied by the power management circuit 300 may be supplied to a semiconductor chip such as the controller 120 or the memory 110 through the package ball PKGB and the bump BMP electrically connected to the package ball PKGB.

The controller 120 or memory 110 included in the storage device 100 may receive other power or control signals through another package ball PKGB included in the package substrate 130. For example, the controller 120 may receive a signal transmitted by the host device 200 of FIG. 1 through the package ball PKGB and the bump BMP.

The storage device 100 may include a plurality of memories 110 or may include a plurality of controllers 120. Various control structures may be provided by the plurality of controllers 120 included in the storage device 100.

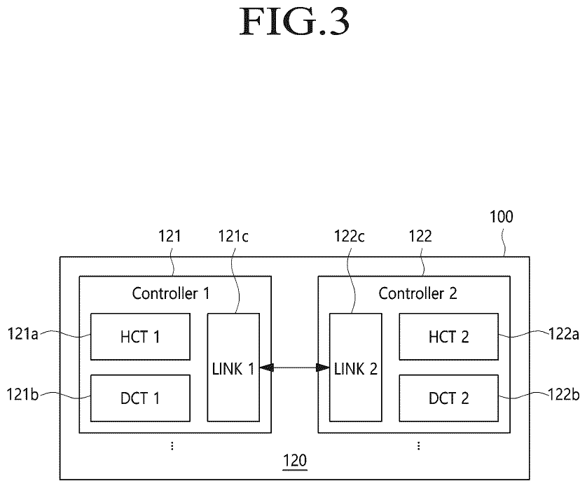

FIG. 3 is a view illustrating a schematic configuration of a plurality of controllers 120 included in a storage device 100 according to embodiments of the present disclosure.

Referring to FIG. 3, the storage device 100 may include the plurality of controllers 120, e.g., a first controller 121 and a second controller 122.

In some embodiments, the storage device 100 may include at least one memory 110. FIG. 3 illustrates an embodiment in which the storage device 100 includes two controllers 120, but embodiments of the present disclosure may also be applied even when three or more controllers 120 are included in the storage device 100.

The first controller 121 may include a first host interface 121a, a first memory interface 121b, and a first link interface (LINK 1) 121c. The first host interface 121a may be referred to as a first host control top (HCT1), and the first memory interface 121b may be referred to as a first device control top (DCT1). The second controller 122 may include a second host interface 122a, a second memory interface 122b, and a second link interface (LINK 2) 122c. The second host interface 122a may be referred to as a second host control top (HCT2), and the second memory interface 122b may be referred to as a second device control top (DCT2).

The first host interface 121a and the second host interface 122a may provide a function of communicating with the host device 200 of FIG. 1.

In some embodiments, one of the first host interface 121a and the second host interface 122a may communicate with the host device 200. For example, the first host interface 121a may communicate with the host device 200, and the second host interface 122a may be in an inactive state. The first controller 121 may be referred to as a main controller, and the second controller 122 may be referred to as a sub controller.

The first memory interface 121b and the second memory interface 122b may provide a function of communicating with the memory 110 of FIG. 1. The number of memory interfaces included in each controller 120 may be two or more. Some memories 110 may be controlled by the first controller 121, and other memories 110 may be controlled by the second controller 122.

All of the memory interfaces included in each controller 120 may be activated to communicate with separate memories 110.

Alternatively, some of the memory interfaces included in each controller 120 may be activated. For example, the second memory interface 122b included in the second controller 122 may be in an active state, and the second memory interface 121b included in the first controller 121 may be in an inactive state.

The first link interface 121c and the second link interface 122c may provide a function of performing communication between the controllers 120. When the first controller 121 communicates with the host device 200, a command or data may be transmitted to the second controller 122 through the first link interface 121c.

As such, communication between the host device 200, the controller 120, and the memory 110 may be performed by each interface included in the first controller 121 and the second controller 122.

As in the above-described embodiment, the components included in the first controller 121 and the second controller 122 may correspond to each other, and some of the components may be activated and operated. Alternatively, the components included in the first controller 121 and the second controller 122 may be different from each other. For example, the first controller 121 may consist of the first host interface 121a and the first link interface 121c, and the second controller 122 may consist of the second memory interface 122b and the second link interface 122c.

Each of the first controller 121 and the second controller 122 may be implemented in the form of a single chip. Alternatively, various interfaces included in each of the first controller 121 and the second controller 122 may be implemented in the form of separate chipsets. Each interface may be implemented as a chiplet, or some functions of each interface may be combined to be implemented as a chiplet.

Since a plurality of controllers 120 are included in the storage device 100 and each of the plurality of controllers 120 provides various interfaces, the capacity of the memory 110 provided by the storage device 100 may be increased and performance may be enhanced.

Embodiments of the present disclosure may provide a way to efficiently implement a structure that supplies signals to each semiconductor chip in a structure in which the number of semiconductor chips included in the storage device 100 has increased.

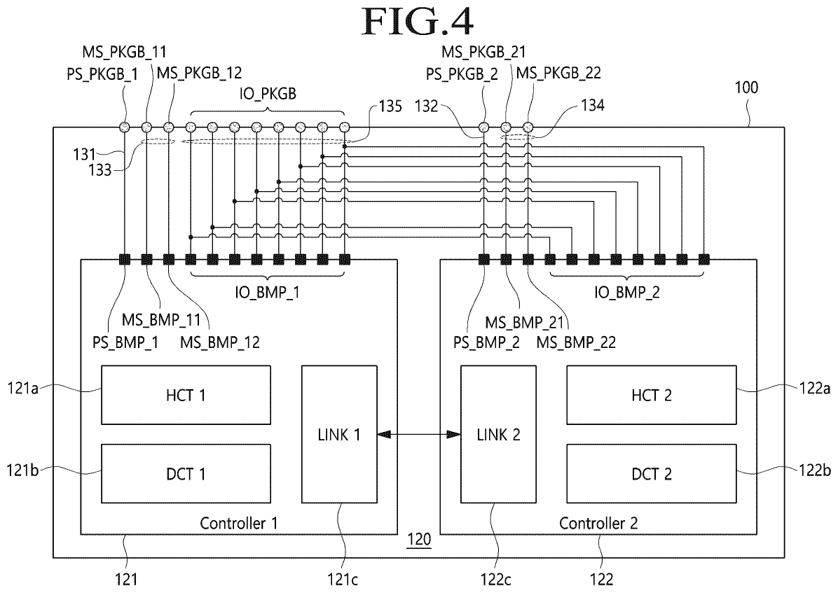

FIG. 4 is a view illustrating a structure of supplying signals to a plurality of controllers 120 included in a storage device 100 according to embodiments of the present disclosure.

Referring to FIG. 4, a first controller 121 and a second controller 122 are included in the storage device 100. The first controller 121 may include a first host interface 121a, a first memory interface 121b, and a first link interface (LINK1) 121c. The first host interface 121a may be referred to as a first host control top (HCT1), and the first memory interface 121b may be referred to as a first device control top (DCT1). The second controller 122 may include a second host interface 122a, a second memory interface 122b, and a second link interface (LINK2) 122c. The second host interface 122a may be referred to as a second host control top (HCT2), and the second memory interface 122b may be referred to as a second device control top (DCT2).

Some components included in the first controller 121 and the second controller 122 may be in an active or inactive state. In some embodiments, the first controller 121 and the second controller 122 may include only activated components.

Each of the first controller 121 and the second controller 122 may include a plurality of bumps BMP. Each of the first controller 121 and the second controller 122 may receive power or a signal through the plurality of bumps BMP.

The first controller 121 may include, e.g., a first power supply signal bump PS_BMP_1, a first mode signal bump MS_BMP_11, MS_BMP_12, and a plurality of first input and output (input/output) bumps IO_BMP_1.

The second controller 122 may include, e.g., a second power supply signal bump PS_BMP_2, a second mode signal bump MS_BMP_21, MS_BMP_22, and a plurality of second input/output bumps IO_BMP_2.

At least some of the plurality of bumps BMP included in the first controller 121 and the second controller 122 may be electrically connected to the package ball PKGB included in the package substrate 130.

The first power signal bump PS_BMP_1 may be electrically connected to the first power signal package ball PS_PKGB_1 through the first power signal line 131. The second power signal bump PS_BMP_2 may be electrically connected to the second power signal package ball PS_PKGB_2 through the second power signal line 132.

The first power signal bump PS_BMP_1 and the second power signal bump PS_BMP_2 may be electrically separated from each other. The first power signal line 131 and the second power signal line 132 may be lines disposed on the package substrate 131 or included in the package substrate 131.

The first power signal package ball PS_PKGB_1 and the second power signal package ball PS_PKGB_2 may receive power signals from the outside.

For example, the first power signal package ball PS_PKGB_1 and the second power signal package ball PS_PKGB_2 may receive power from the power management circuit 300 and provide the power to the first controller 121 and the second controller 122.

Each of the first controller 121 and the second controller 122 may operate based on power received through the first power signal bump PS_BMP_1 and the second power signal bump PS_BMP_2.

The first mode signal bumps MS_BMP_11 and MS_BMP_12 may be electrically connected to the first mode signal package balls MS_PKGB_11 and MS_PKGB_12 through the first mode signal line 133. The second mode signal bumps MS_BMP_21 and MS_BMP_22 may be electrically connected to the second mode signal package balls MS_PKGB_21 and MS_PKGB_22 through the second mode signal line 134.

The first mode signal line 133 and the second mode signal line 134 may be disposed on the package substrate 130 or may be included in the package substrate 130.

The first controller 121 and the second controller 122 may operate as a main controller or a sub controller based on a signal input through a mode signal bump.

For example, the signal of “1” may be input to one first mode signal bump MS_BMP_11 of the first controller 121 and the signal of “0” may be input to the other first mode signal bump MS_BMP_12. The signal of “0” may be input to one second mode signal bump MS_BMP_21 of the second controller 122 and the signal of “1” may be input to the other second mode signal bump MS_BMP_22. The first controller 121 may operate as a main controller, and the second controller 122 may operate as a sub controller. The first controller 121 may communicate with the host device 200 and the second controller 122. The first controller 121 may communicate with the memory 110. The second controller 122 may communicate with the first controller 121 and the memory 110.

Among the bumps BMP included in the first controller 121 and the second controller 122, the bumps other than the power signal bump and the mode signal bump may share the package ball PKGB. For example, the first input/output bump IO_BMP_1 and the second input/output bump IO_BMP_2 may be electrically connected to the same input/output package ball IO_PKGB through the input/output line 135.

The first input/output bump IO_BMP_1 and the second input/output bump IO_BMP_2 may be electrically connected to the input/output package ball IO_PKGB.

The first input/output bump IO_BMP_1 and the second input/output bump IO_BMP_2 electrically connected to the shared input/output package ball IO_PKGB may be one of various bumps BMP included in the first controller 121 and the second controller 122.

For example, the first input/output bump IO_BMP_1 and the second input/output bump IO_BMP_2 may include a bump BMP for communication such as inter-integrated circuit (I2C) and improved inter-integrated circuit (I3C), a bump BMP for control signals such as general purpose input/output (GPIO), and a bump BMP for debugging such as universal asynchronous receiver/transmitter (UART).

The first input/output bump IO_BMP_1 and the second input/output bump IO_BMP_2 may include a bump BMP for testing.

The bump BMP for testing may include, e.g., a test mode bump, a test input bump, and a test output bump. The test type of the controller 120 may be determined according to a signal input to the test mode bump. An input signal for testing may be received through the test input bump, and an output signal according to the test may be output through the test output bump.

The package ball PKGB electrically connected to the test input/output bump may be referred to as a test package ball.

Even when the test input/output bump of the first controller 121 and the test input/output bump of the second controller 122 are electrically connected to the shared test package ball, the test for each controller 120 may be performed by controlling the input/output states of the bumps BMP of the first controller 121 and the second controller 122. The control of the input/output state may be performed by signals transmitted and received between the first controller 121 and the second controller 122.

Alternatively, the controller 120 to be tested may be determined based on a signal input through the mode signal bump.

Each of the first controller 121 and the second controller 122 may set the input/output state of the test input/output bump based on a signal input to the first mode signal bumps MS_BMP_11 and MS_BMP_12 and the second mode signal bumps MS_BMP_21 and MS_BMP_22.

The test may be performed on the controller 120 in which the input/output state of the test input/output bump is set as the output state by setting the input/output state of the test input/output bump of the controller 120 to be tested between the first controller 121 and the second controller 122 as an output state, and setting the input/output state of the test input/output bump of the other controller 120 as an input state.

By sharing the package balls PKGB connected to various input/output bumps in addition to the bumps BMP where signals for testing are input/output as described above, the number of package balls PKGB included in the storage device 100 may be reduced.

In a structure in which the package balls PKGB included in the storage device 100 are shared by the plurality of controllers 120, the power signal bumps of each controller 120 may be electrically connected to separate package balls PKGB separated from each other. The first power signal package ball PS_PKGB_1 and the second power signal package ball PS_PKGB_2 may be disposed to be separated from each other.

The first controller 121 and the second controller 122 may operate based on power received through the first power signal package ball PS_PKGB_1 and the second power signal package ball PS_PKGB_2, respectively.

The first controller 121 and the second controller 122 may perform a booting operation based on signals received through the first power signal package ball PS_PKGB_1 and the second power signal package ball PS_PKGB_2, respectively. The booting operation of the first controller 121 and the second controller 122 may be performed based on a signal transmitted and received between the first controller 121 and the second controller 122.

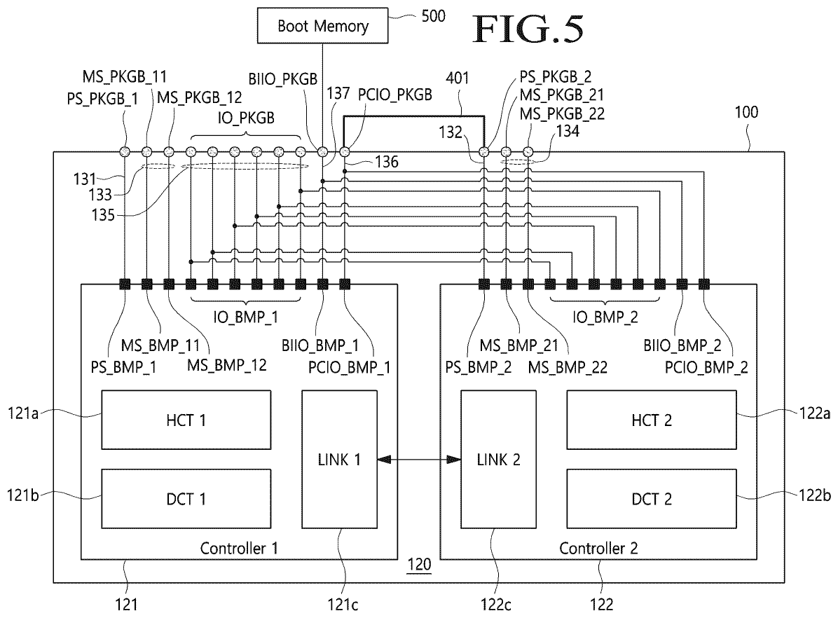

FIG. 5 is a view illustrating another structure of supplying signals to a plurality of controllers 120 included in a storage device 100 according to embodiments of the present disclosure.

Referring to FIG. 5, the first controller 121 may include a first power signal bump PS_BMP_1, first mode signal bumps MS_BMP_11 and MS_BMP_12, a first input/output bump IO_BMP_1, a first boot image input/output bump BIIO_BMP_1, and a first power control input/output bump PCIO_BMP_1.

The second controller 122 may include a second power signal bump PS_BMP_2, second mode signal bumps MS_BMP_21 and MS_BMP_22, a second input/output bump IO_BMP_2, a second boot image input/output bump BIIO_BMP_2, and a second power control input/output bump PCIO_BMP_2.

The first power signal bump PS_BMP_1 may be electrically connected to the first power signal package ball PS_PKGB_1 through the first power signal line 131. The first mode signal bumps MS_BMP_11 and MS_BMP_12 may be electrically connected to the first mode signal package balls MS_PKGB_11 and MS_PKGB_12 through the first mode signal line 133.

The second power signal bump PS_BMP_2 may be electrically connected to the second power signal package ball PS_PKGB_2 through the second power signal line 132. The second mode signal bumps MS_BMP_21 and MS_BMP_22 may be electrically connected to the second mode signal package balls MS_PKGB_21 and MS_PKGB_22 through the second mode signal line 134.

The first input/output bump IO_BMP_1 and the second input/output bump IO_BMP_2 may be electrically connected to the input/output package ball IO_PKGB shared through the input/output line 135.

Among the first input/output bumps IO_BMP_1, the first power control input/output bump PCIO_BMP_1 may be electrically connected to the power control package ball PCIO_PKGB through the power control line 136. The power control package ball PCIO_PKGB may be electrically connected to the second power signal package ball PS_PKGB_2 through a connection line 401. For example, the connection line 401 may be disposed on the base substrate 400 or may be included in the base substrate 400.

In some embodiments, the first power control input/output bump PCIO_BMP_1 may be electrically connected to the second power signal bump PS_BMP_2 through line on the package substrate 130.

A structure in which a signal output through the first power control input/output bump PCIO_BMP_1 may be input to the second power signal bump PS_BMP_2 through the second power signal package ball PS_PKGB_2 may be provided.

The first power control input/output bump PCIO_BMP_1 may be electrically connected to the second power control input/output bump PCIO_BMP_2 through the power control line 136. The second power control input/output bump PCIO_BMP_2 may be electrically connected to the power control package ball PCIO_PKGB.

The first boot image input/output bump BIIO_BMP_1 of the first input/output bump IO_BMP_1 may be electrically connected to the boot image package ball BIIO_PKGB through the boot image line 137. The boot image package ball BIIO_PKGB may be electrically connected to a boot memory 500 in which a boot image used during booting is stored. The boot memory 500 may be a non-volatile memory such as a flash memory, but is the embodiments are not limited thereto.

The first boot image input/output bump BIIO_BMP_1 may be electrically connected to the second boot image input/output bump BIIO_BMP_2 through the boot image line 137. The second boot image input/output bump BIIO_BMP_2 may be electrically connected to the boot image package ball BIIO_PKGB.

In a structure in which some of the package balls PKGB are shared by the first controller 121 and the second controller 122, the booting operation of the first controller 121 and the second controller 122 may be performed by a structure in which the first power control input/output bump PCIO_BMP_1 of the first controller 121 and the second power signal bump PS_BMP_2 of the second controller 122 are electrically connected.

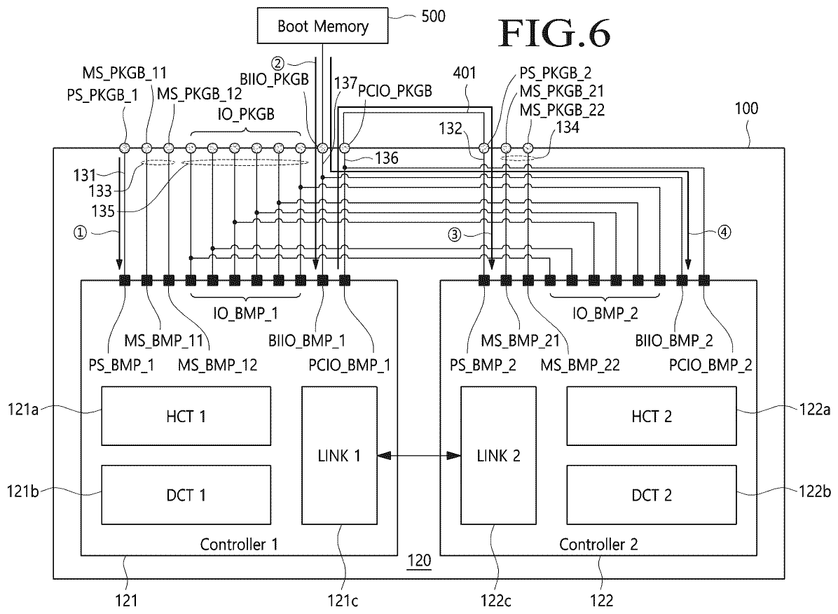

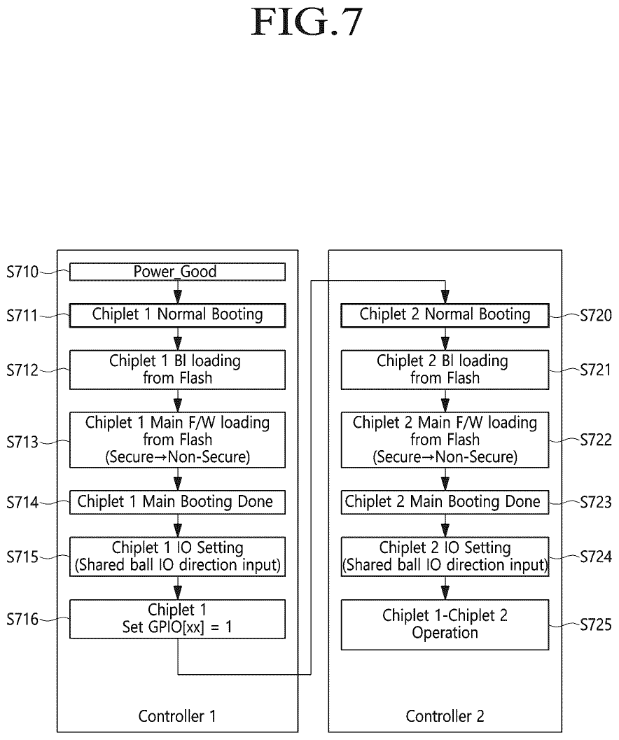

FIGS. 6 and 7 are views illustrating a booting method of a plurality of controllers 120 included in the storage device 100 shown in FIG. 5.

Referring to FIG. 6, the first controller 121 may perform a booting operation based on a signal received through the first power signal package ball PS_PKGB_1, as shown in \textcircled{1}. The first controller 121 may receive a power good signal from the power management circuit 300, for example. The power good signal may be a signal indicating that a power output from the power management circuit 300 is normal. The power management circuit 300 may output the power good signal when the power is equal to or greater than threshold level required, or the power is in a range required for operating the storage device 100.

When the power good signal is received according to power supply by the power management circuit 300, as shown in \textcircled{2}, the first controller 121 may perform a booting operation by receiving a boot image from the boot memory 500.

The first controller 121 may maintain the signal level of the first power control input/output bump PCIO_BMP_1 as the first level during a period when the booting operation is performed.

When the booting operation is completed, the first controller 121 may change the signal level of the first power control input/output bump PCIO_BMP_1 to a second level different from the first level. According to a change in the signal level of the first power control input/output bump PCIO_BMP_1, a signal indicating the start of the booting operation may be input to the second power signal bump PS_BMP_2.

The second controller 122 may perform a booting operation based on a signal input to the second power signal bump PS_BMP_2. The second controller 122 may wait for a period when the booting operation of the first controller 121 is performed and the signal level of the first power control input/output bump PCIO_BMP_1 is the first level. When the signal level of the first power control input/output bump PCIO_BMP_1 is changed to the second level, the second controller 122 may perform a booting operation based on the corresponding signal.

In some embodiments, the second controller 122 may also receive a power good signal from the power management circuit 300 through the second power signal package ball PS_PKGB_2 and perform a booting operation. In the embodiments, the booting timing of the first controller 121 and the second controller 122 may be controlled by the power management circuit 300 or an external control signal.

Since the second controller 122 performs a booting operation based on a signal received from the first controller 121, the booting operation may be sequentially performed in a semiconductor package including a plurality of semiconductor chips.

A signal supplied to the second power signal package ball PS_PKGB_2 may be supplied through the power control package ball PCIO_PKGB shared by the first power control input/output bump PCIO_BMP_1 of the first controller 121 and the second power control input/output bump PCIO_BMP_2 of the second controller 122. A structure for sequential booting operations of the first controller 121 and the second controller 122 may be implemented without adding a package ball PKGB.

When a signal indicating the start of the booting operation is received through the second power signal bump PS_BMP_2, the second controller 122 may receive a boot image from the boot memory 500 through the boot image package ball BIIO_PKGB as shown in 4). The boot image may be input to the second controller 122 through the boot image line 137 and the second boot image input/output bump BIIO_BMP_2. During the corresponding period, the input/output state of the first boot image input/output bump BIIO_BMP_1 of the first controller 121 may be set to an input state, so as not to affect the operation of the second controller 122 using the second boot image input/output bump BIIO_BMP_2.

The process of the booting operation performed by the first controller 121 and the second controller 122 may be divided as follows.

Referring to FIG. 7, booting operations performed by the first controller 121 and the second controller 122 are separately shown. In FIG. 7, the first controller 121 is referred to as a first chiplet, and the second controller 122 is referred to as a second chiplet.

The first controller 121 may receive a power good signal from the power management circuit 300 (S710). Upon receiving the power good signal, the first controller 121 may perform a booting operation (S711). The first controller 121 may load a boot image (BI) from the boot memory (e.g., flash memory) 500 (S712). The first controller 121 may perform a booting operation by loading the main firmware (FW or F/W) from the boot memory 500 (S713). The main firmware stored in a secure region may be loaded on a non-secure region. The secure region and the non-secure region may be physical memory regions. The secure region may mean a region which is accessible and usable by only the controller 120. The first controller 121 may complete the booting operation (S714).

When the booting operation is completed, the first controller 121 may set the input/output (I/O or IO) state of the input/output bump (S715).

For example, the first controller 121 may set the input/output state of the first input/output bump IO_BMP_1 as an input state.

The first controller 121 may set the input/output state of the first input/output bump IO_BMP_1 as an input state to share the package ball PKGB (i.e., shared ball IO direction input) and may not affect the operation of the second controller 122 which is to subsequently perform a booting operation.

The first controller 121 may set only the input/output state of the first power control input/output bump PCIO_BMP_1 as an output state and set the input/output state of the remaining first input/output bump IO_BMP_1 as an input state. For example, the first controller 121 may change only the setting value of GPIO [xx] corresponding to the first power control input/output bump PCIO_BMP_1 from “0” to “1” (S716).

According to the change in the signal level or setting value of the first power control input/output bump PCIO_BMP_1, the booting operation may be started by the second controller 122 (S720). The second controller 122 may load a boot image (BI) from the boot memory (e.g., flash memory) 500 (S721). The second controller 122 may perform a booting operation by loading the main firmware (F/W) from the boot memory 500 (S722). The main firmware stored in a secure region may be loaded on a non-secure region. The secure region and the non-secure region may be physical memory regions. The secure region may mean a region which is accessible and usable by only the controller 120. The booting operation by the second controller 122 may be completed (S723).

When the booting operation is completed, the second controller 122 may set the input/output state of the second input/output bump IO_BMP_2 (S724).

Since the booting of the first controller 121 and the second controller 122 is completed, the first controller 121 and the second controller 122 may communicate with each other through the first link interface 121c and the second link interface 122c to set input/output states of the first input/output bump IO_BMP_1 and the second input/output bump IO_BMP_2 (S725).

In a structure of sharing the input/output package ball IO_PKGB electrically connected to the first input/output bump IO_BMP_1 and the second input/output bump IO_BMP_2, the operations of the first controller 121 and the second controller 122 may be normally performed by adjusting the input/output states of the first input/output bump IO_BMP_1 and the second input/output bump IO_BMP_2.

In some embodiments, the booting method of the controller 120 included in the storage device 100 according to embodiments of the present disclosure may be similarly applied even when three or more controllers 120 are included.

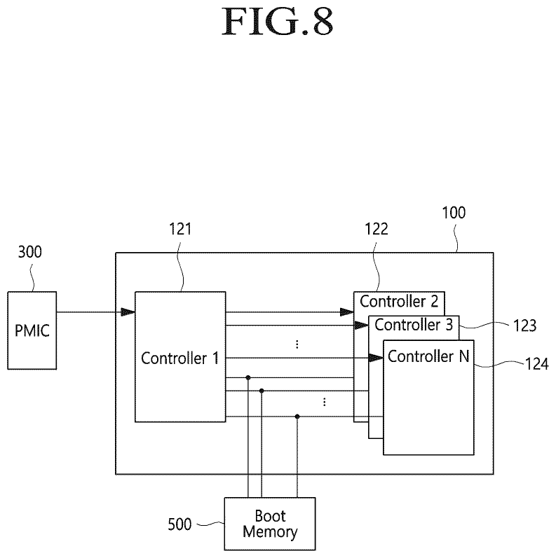

FIG. 8 is a view illustrating a connection structure between a plurality of controllers 120 included in a storage device 100 according to embodiments of the present disclosure.

Referring to FIG. 8, N controllers 121, 122, 123, and 124 are included in the storage device 100. The N controllers 120 included in the storage device 100 may be connected in a daisy chain method, for example. In this embodiment, the booting operation of the second controller 122 may start based on the output signal of the first controller 121, and the booting operation of the third controller 123 may start based on the output signal of the second controller 122.

Alternatively, as illustrated in FIG. 8, the booting operation of the remaining controller 120 may be performed based on the output signal of the first controller 121 corresponding to the main controller.

For example, the first controller 121 may perform a booting operation based on a power good signal output from the power management circuit 300. When the booting operation is completed, the first controller 121 may transmit a signal indicating the start of the booting operation to the second controller 122.

When the booting operation of the second controller 122 is completed, the first controller 121 may transmit a signal indicating the start of the booting operation to the third controller 123.

In some embodiments, the power control package ball PCIO_PKGB electrically connected to the first power control input/output bump PCIO_BMP_1 of the first controller 121 may be electrically connected to the second power signal package ball PS_PKGB_2 electrically connected to the second power signal bump PS_BMP_2 of the second controller 122 and the third power signal package ball electrically connected to the third power signal bump of the third controller 123. The booting operations of the plurality of controllers 120 may be sequentially performed by adjusting the input/output state of the input/output bump of the controller 120 where the booting operation has been completed.

Since the booting operation of the remaining controller 120 is controlled by the first controller 121, even if an operation error occurs in one of the sub controllers (remaining controllers 120), the booting operation of the remaining sub controller may be normally performed as compared to the daisy chain method.

As described above, embodiments of the present disclosure may facilitate the implementation of a semiconductor device by arranging at least some of the package balls PKGB in a shared structure as a shared structure in a semiconductor device such as the storage device 100 including a plurality of semiconductor chips. Further, the booting operations of the plurality of semiconductor chips may be performed sequentially through the electrical connection between the input/output bump of the main controller (main semiconductor chip) and the power signal bump of the sub controller (sub semiconductor chip).

Further, embodiments of the present disclosure may further reduce the number of package balls PKGB included in the semiconductor device through a shared structure of the package ball PKGB other than the power signal package ball.

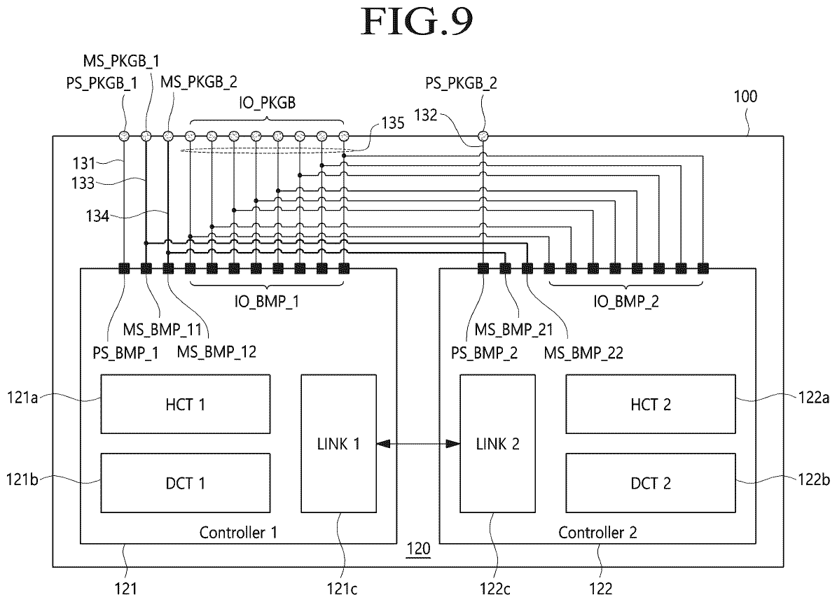

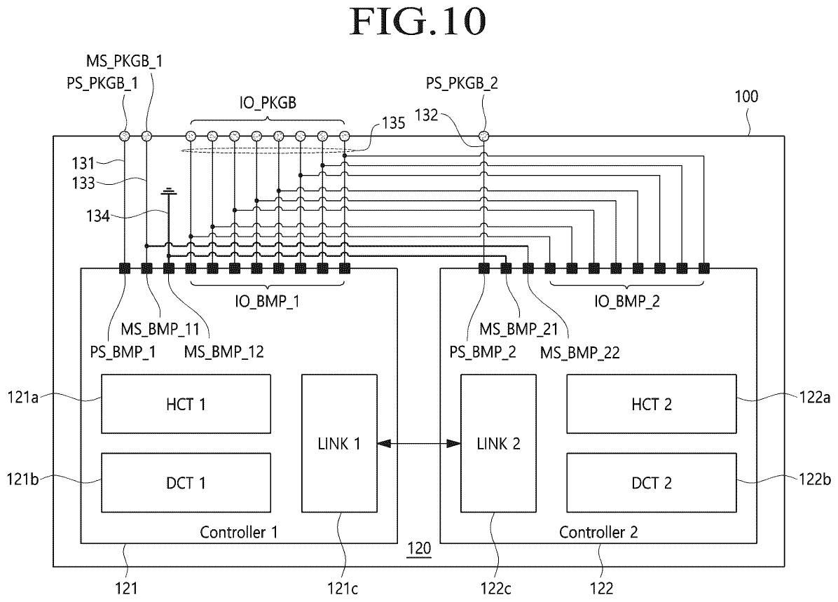

FIGS. 9 and 10 are views illustrating another structure of supplying signals to a plurality of controllers 120 included in a storage device 100 according to embodiments of the present disclosure.

Referring to FIG. 9, the first controller 121 may include a first power supply signal bump PS_BMP_1, first mode signal bumps MS_BMP_11 and MS_BMP_12 and a first input/output bump IO_BMP_1. The second controller 121 may include a second power supply signal bump PS_BMP_2, second mode signal bumps MS_BMP_21 and MS_BMP_22, and a second input/output bump IO_BMP_2.

The first power signal bump PS_BMP_1 may be electrically connected to the first power signal package ball PS_PKGB_1 through the first power signal line 131. The second power signal bump PS_BMP_2 may be electrically connected to the second power signal package ball PS_PKGB_2 through the second power signal wiring 132.

One MS_BMP_11 of the first mode signal bumps MS_BMP_11 and MS_BMP_12 may be electrically connected to the first mode signal package ball MS_PKGB_1 through the first mode signal line 133. One MS_BMP_22 of the second mode signal bumps MS_BMP_21 and MS_BMP_22 may be electrically connected to the first mode signal package ball MS_PKGB_1 through the first mode signal line 133.

The other MS_BMP_12 of the first mode signal bumps MS_BMP_11 and MS_BMP_12 may be electrically connected to the second mode signal package ball MS_PKGB_2 through the second mode signal line 134. The other MS_BMP_21 of the second mode signal bumps MS_BMP_21 and MS_BMP_22 may be electrically connected to the second mode signal package ball MS_PKGB_2 through the second mode signal line 134.

In a structure in which the first mode signal bumps MS_BMP_11 and MS_BMP_12 and the second mode signal bumps MS_BMP_21 and MS_BMP_22 share the package ball PKGB, the modes of the first controller 121 and the second controller 122 may be controlled by signals supplied to the first mode signal package ball MS_PKGB_1 and the second mode signal package ball MS_PKGB_2.

For example, a signal of a level “1” may be supplied to the first mode signal package ball MS_PKGB_1, and a signal of a level “0” may be supplied to the second mode signal package ball MS_PKGB_2. The first controller 121 may receive “10” through the first mode signal bumps MS_BMP_11 and MS_BMP_12, and the second controller 122 may receive “01” through the second mode signal bumps MS_BMP_21 and MS_BMP_22. The first controller 121 may operate as a main controller, and the second controller 122 may operate as a sub controller.

As such, the operation mode of the plurality of controllers 120 included in the storage device 100 may be set while further reducing the number of package balls PKGB.

Further, in some embodiments, the number of mode signal package balls may be further reduced and the operation mode of the controller 120 may be set.

Referring to FIG. 10, the first controller 121 may include various bumps BMP and may include first mode signal bumps MS_BMP_11 and MS_BMP_12. The second controller 122 may include various bumps BMP, and may include second mode signal bumps MS_BMP_21 and MS_BMP_22.

One MS_BMP_11 of the first mode signal bumps MS_BMP_11 and MS_BMP_12 and one MS_BMP_22 of the second mode signal bumps MS_BMP_21 and MS_BMP_22 may be electrically connected to the first mode signal package ball MS_PKGB_1 through the first mode signal line 133.

The other MS_BMP_12 of the first mode signal bumps MS_BMP_11 and MS_BMP_12 and the other MS_BMP_21 of the second mode signal bumps MS_BMP_21 and MS_BMP_22 may be electrically connected to each other and grounded. Since it is grounded, a signal of a level “0” may be input to the corresponding mode signal bump.

The first controller 121 and the second controller 122 may set the operation mode based on the signal input through the first mode signal package ball MS_PKGB_1 and the signal input through the grounded second mode signal line 134, and operate as the main or sub controller.

In a structure in which the plurality of controllers 120 are included in the storage device 100, it is possible to reduce the number of package balls PKGB and simply implement a structure for operation mode setting and signal supply for operation of the plurality of controllers 120.

Based on embodiments of the present disclosure described above, the operation delay time of the memory system may be advantageously reduced or minimized. In addition, based on an embodiment of the present disclosure, an overhead occurring in the process of calling a specific function may be advantageously reduced or minimized. Although various embodiments of the present disclosure have been described with particular specifics and varying details for illustrative purposes, those skilled in the art will appreciate that various modifications, additions and substitutions may be made based on what is disclosed or illustrated in this disclosure without departing from the spirit and scope of the present disclosure as defined in the following claims. Furthermore, the embodiments may be combined to form additional embodiments.

What is claimed is:

1. A semiconductor device comprising:
a first semiconductor chip including a first power signal bump and a plurality of first input and output (input/output) bumps, which includes a first power control input/output bump;
a second semiconductor chip including a second power signal bump and a plurality of second input/output bumps;
a first power signal package ball electrically connected to the first power signal bump through a first power signal line;
a second power signal package ball electrically connected to the second power signal bump through a second power signal line; and
a power control package ball electrically connected to the first power control input/output bump through a power control line and electrically connected to the second power signal package ball through a connection line.

2. The semiconductor device of claim 1, wherein the first semiconductor chip performs a booting operation when a power control signal is received through the first power signal bump and, while performing the booting operation, maintains a signal level of the first power control input/output bump as a first level.

3. The semiconductor device of claim 2, wherein the first semiconductor chip changes the signal level of the first power control input/output bump from the first level to a second level when the booting operation is completed.

4. The semiconductor device of claim 3, wherein the second semiconductor chip performs the booting operation when the signal level of the first power control input/output bump is changed to the second level.

5. The semiconductor device of claim 3, wherein the first semiconductor chip sets an input/output state of at least one remaining input/output bump except for the first power control input/output bump among the plurality of first input/output bumps to an input state when the signal level of the first power control input/output bump is changed to the second level.

6. The semiconductor device of claim 2, wherein the plurality of first input/output bumps includes a first boot image input/output bump, and
the first semiconductor chip receives a boot image from an outside through the first boot image input/output bump, and performs the booting operation based on the boot image.

7. The semiconductor device of claim 6, wherein the plurality of second input/output bumps includes a second boot image input/output bump, which is electrically connected to the first boot image input/output bump through a boot image line.

8. The semiconductor device of claim 7, further comprising a boot image package ball electrically connected to the first boot image input/output bump and the second boot image input/output bump through the boot image line.

9. The semiconductor device of claim 1, further comprising at least one mode signal package ball,
wherein the first semiconductor chip further includes at least one first mode signal bump, and the second semiconductor chip further includes at least one second mode signal bump, and
wherein the at least one mode signal package ball is electrically connected to at least one of the at least one first mode signal bump or the at least one second mode signal bump.

10. The semiconductor device of claim 9, wherein the at least one mode signal package ball includes:
at least one first mode signal package ball electrically connected to the at least one first mode signal bump through a first mode signal line; and
at least one second mode signal package ball electrically connected to the at least one second mode signal bump through a second mode signal line electrically separated from the first mode signal line.

11. The semiconductor device of claim 9, wherein the at least one mode signal package ball includes a first mode signal package ball electrically connected to one of the at least one first mode signal bump and one of the at least one second mode signal bump through a first mode signal line.

12. The semiconductor device of claim 11, wherein the at least one mode signal package ball further includes a second mode signal package ball electrically connected to another one of the at least one first mode signal bump and another one of the at least one second mode signal bump through a second mode signal line.

13. The semiconductor device of claim 11, wherein the other one of the at least one first mode signal bump and the other one of the at least one second mode signal bump are electrically connected to each other and grounded.

14. The semiconductor device of claim 9, further comprising at least one test package ball,
wherein the plurality of first input/output bumps includes at least one first test input/output bump, and the plurality of second input/output bumps includes at least one second test input/output bump, and
wherein the at least one test package ball is electrically connected to at least one of the at least one first test input/output bump or the at least one second test input/output bump.

15. The semiconductor device of claim 14, wherein a test target is determined between the first semiconductor chip and the second semiconductor chip based on a test control signal input through the at least one first mode signal bump and the at least one second mode signal bump.

16. The semiconductor device of claim 1, wherein the first power signal package ball and the second power signal package ball are electrically separated from each other.

17. The semiconductor device of claim 1, further comprising a third semiconductor chip including a third power signal bump and a plurality of third input/output bumps,
wherein the third power signal bump is electrically separated from the plurality of second input/output bumps, and is electrically connected to at least one other than the first power control input/output bump, among the plurality of first input/output bumps.

18. A semiconductor device comprising:
a first controller including a first power signal bump and a plurality of first input and output (input/output) bumps, the first power signal bump electrically connected to a first power signal package ball;
a second controller including a second power signal bump and a plurality of second input/output bumps, the second power signal bump electrically separated from the first power signal bump and electrically connected to at least one of the plurality of first input/output bumps; and
at least one memory receiving a signal from at least one of the first controller or the second controller.

19. A semiconductor module comprising:
a base substrate;
a package substrate disposed on the base substrate and including a first power signal package ball, a second power signal package ball, and a power control package ball;
a first semiconductor chip disposed on the package substrate and including a first power signal bump and a first power control input/output bump, the first power signal bump electrically connected to the first power signal package ball through a first power signal line, the first power control input and output (input/output) bump electrically connected to the power control package ball through a power control line; and
a second semiconductor chip disposed on the package substrate and including a second power signal bump electrically connected to the second power signal package ball through a second power signal line, and electrically connected to the first power control input/output bump.

20. The semiconductor module of claim 19, further comprising a power management circuit disposed on the base substrate,
wherein the first power signal package ball is electrically connected to the power management circuit, and
wherein the second power signal package ball is electrically connected to the power control package ball through a connection line included in the base substrate.
